(19) United States
(12) Patent Application Publication
(10) Pub. No.: US 2011/0053485 A1
(43) Pub. Date: Mar. 3, 2011

(54) SERVER RACK WITH BAFFLE DEVICE

(75) Inventors: WEI-CHAO HUANG, Tu-Cheng (TW); CHIH-MING HUANG, Tu-Cheng (TW); CHUNG-PING LIU, Tu-Cheng (TW)

(73) Assignee: HON HAI PRECISION INDUSTRY CO., LTD., Tu-Cheng (TW)

(21) Appl. No.: 12/616,743

(22) Filed: Nov. 11, 2009

(30) Foreign Application Priority Data
Aug. 28, 2009 (CN) 200910306251.1

(51) Int. Cl. H05K 5/02

(52) U.S. Cl. 454/184

(57) ABSTRACT

A server rack for receiving a plurality of modules includes two parallel side plates, a clapboard, and a baffle device. The clapboard is disposed between the two side plates substantially perpendicular to the two side plates to form a receiving space. The receiving space defines an air inlet and a module entry opposite to the air inlet. The baffle device is received in the receiving space. The baffle device includes two resisting assemblies installed on the two side plates oppositely. Each resisting assembly includes a baffle. The baffle includes a securing portion and a latching portion opposite to the securing portion. The securing portion of each baffle is rotatably secured on the corresponding side plate. A total length of the two baffles is larger than the width of the receiving space. The two baffles are inclined toward the air inlet. The two latching portions of the two baffles are latched facing the air inlet, to cover the module entry when no module is received in the receiving space.

### BACKGROUND

1. Technical Field

The present disclosure relates to server racks and, particularly, to a server rack with a baffle device.

2. Description of Related Art

Generally, server racks define a number of receiving spaces for receiving a number of modules. A server rack defines an air inlet and a module entry. The air inlet is communicated with the receiving spaces for introducing airflow to cool the modules when the modules are operating. Additionally, two baffles are mounted on opposite sidewalls of a receiving space, close to the module entry by torsion springs. When no module is received in the receiving space, the two baffles are abutted by the torque force of the torsion springs to cover the module entry. When a module is inserted into the receiving space through the module entry, the module overcomes the torque force of the torsion springs to separate the two baffles. However, when the module is removed from the corresponding receiving space, airflow for cooling the server rack will overcome the torque force and flow out of the server rack from the module entry instead of flowing to cool other modules received in other receiving spaces of the server rack.

Therefore, it is desirable to provide a server rack with a baffle device which can overcome or at least alleviate the above-mentioned problem.

### BRIEF DESCRIPTION OF THE DRAWINGS

FIG. 1 is an exploded view of a server rack used for receiving a number of modules according to an exemplary embodiment.

FIG. 2 is an isometric view of the server rack FIG. 1.

FIG. 3 is an enlarged view of the section III, shown in FIG. 2.

FIG. 4 is similar to FIG. 2, but showing the section III of FIG. 2 from another angle.

FIG. 5 is a schematic view showing a module is received in the server rack of FIG. 2.

### DETAILED DESCRIPTION

Embodiments of the disclosure will now be described in detail with reference to the accompanying drawings.

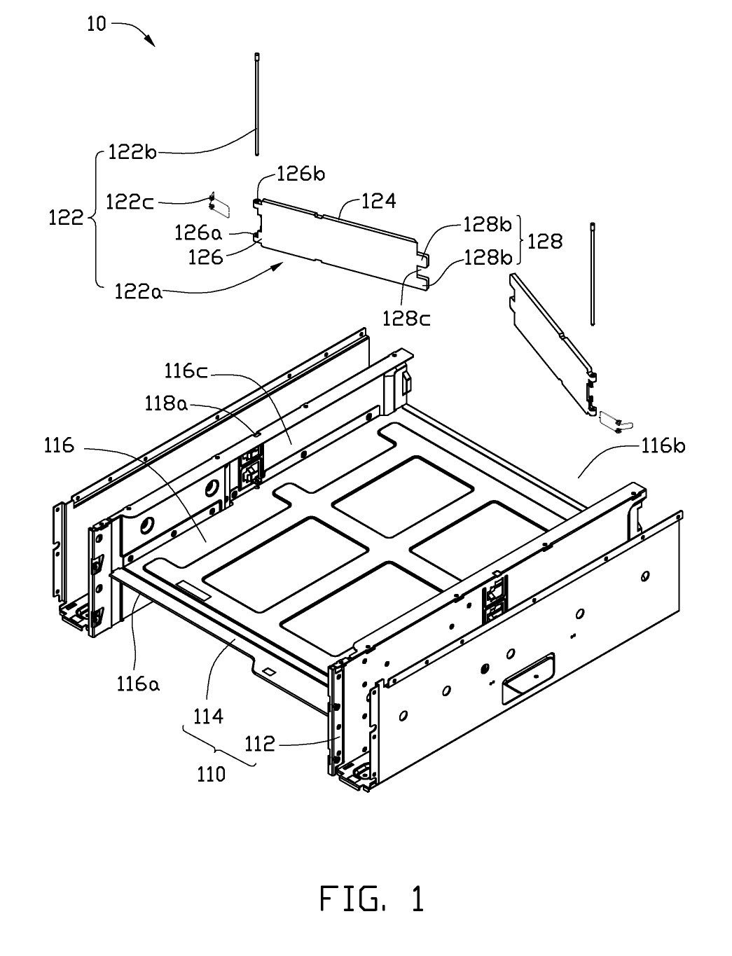

Referring to FIGS. 1-2 and 5, a server rack 10 used for receiving modules 20 according to an exemplary embodiment includes a body 110 and a baffle device 120. The server rack 10 defines an opening (not shown) for introducing airflow into the server rack 10 to cool any modules 20 received in the server rack 10.

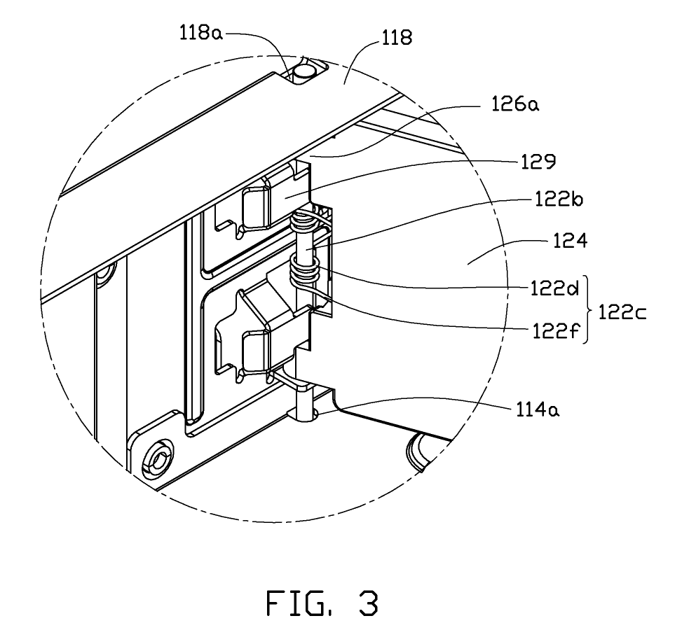

The body 110 includes two parallel side plates 112 and a clapboard 114. The clapboard 114 is disposed between the two side plates 112 and substantially perpendicular to the two side plates 112. The clapboard 114 separates the body 110 into two receiving spaces 116. Each receiving space 116 includes a module entry 116a, an air inlet 116b, and two sidewalls 116c. The module entry 116a is opposite to the air inlet 116b. The air inlet 116b is communicated with the opening for introducing airflow to cool the modules 20. The two sidewalls 116c are formed on the inner sidewalls of the two side plates 112 oppositely. The clapboard 114 defines two first through holes 114a (see FIG. 3) close to the two side plates 112 correspondingly.

Referring to FIG. 3, a curtain board 118 extends from the top of each sidewall 116c toward the receiving space 116. The curtain board 118 defines a second through hole 118a opposite to the corresponding first through hole 114a.

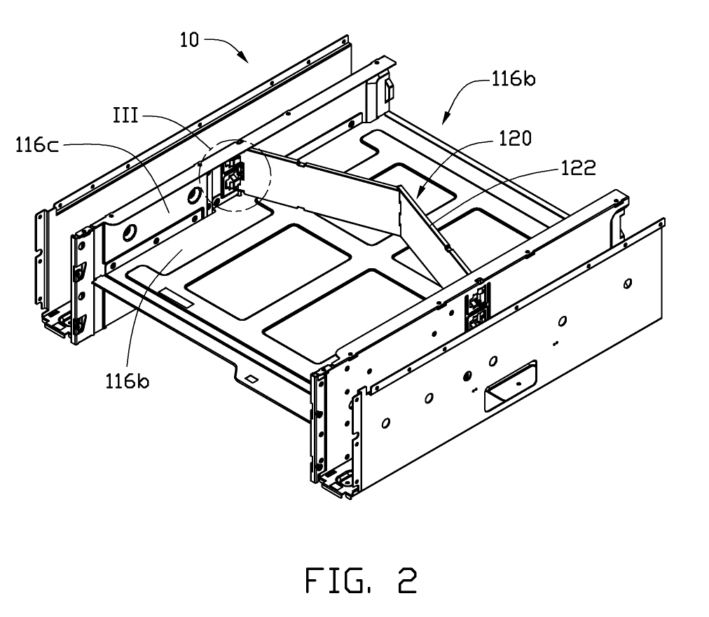

Referring back to FIGS. 1-2, the baffle device 120 is received in the receiving space 116. The baffle device 120 includes two resisting assemblies 122 installed on the two sidewalls 116c of the receiving space 116 oppositely. Each resisting assembly 122 includes a baffle 122a, a shaft 122b, and a torsion spring 122c.

Referring together to FIG. 3, each baffle 122a includes a main body 124, a securing portion 126, and a latching portion 128. The main body 124 is substantially rectangular. The securing portion 126 and the latching portion 128 are disposed on opposite ends of the main body 124. The securing portion 126 includes two securing blocks 126a spaced from each other and rotatably secured to each corresponding sidewall 116c by the shaft 122b. Each securing block 126a defines a third through hole 126b for receiving the shaft 122b. The latching portion 128 includes two latching blocks 128b spaced from each other. A latching groove 128c is formed between the two latching blocks 128b. The latching portions 128 of the two baffles 122a are complementary in structure. That is, the latching blocks 128b of one latching portion 128 are staggered relative to the latching blocks 128b of the other latching portion 128. Additionally, a total length of the two baffles 122a is a little longer than the width of the receiving space 116, thereby, the two latching portions 128 abutted each other when the two baffles 122a are installed in the receiving space 116 oppositely. When the two latching portions 128 abut, one latching block 128b of each latching portion 128 is latched into the latching groove 128c of the other latching portion 128.

The torsion spring 122c includes two coil portions 122d and a resisting portion 122f. The two coil portions 122d are spaced from each other. The resisting portion 122f is connected to the two coil portions 122d.

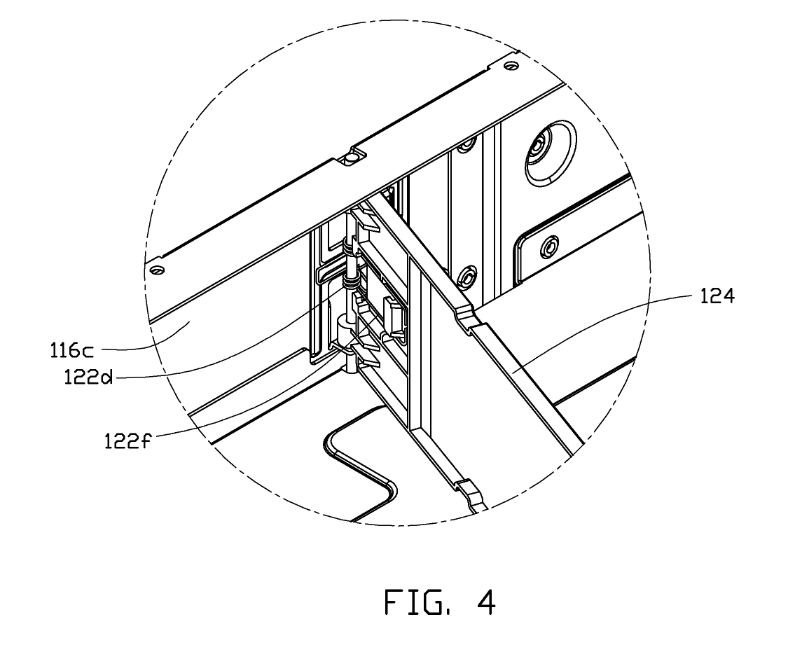

Referring to FIG. 4, to install the resisting assembly 122 to the receiving space 116, firstly the shaft 122b is inserted into the second through hole 118a, the third through hole 126b, the coil portion 122d, and the first through hole 114a in turn to allow the baffle 122a to be secured rotatablely on the sidewall 116c. The coil portions 122d abut against the sidewalls 116c, and the two baffles 122a are pushed to rotate around the shaft 122b toward the module entry 116a under the torque force generated by the resisting portion 122f, thus, the latching portions 128 of the two baffles 122a are latched together, facing the air inlet 116b to prevent the two baffles 122a from being opened by the airflow from the air inlet 116b.

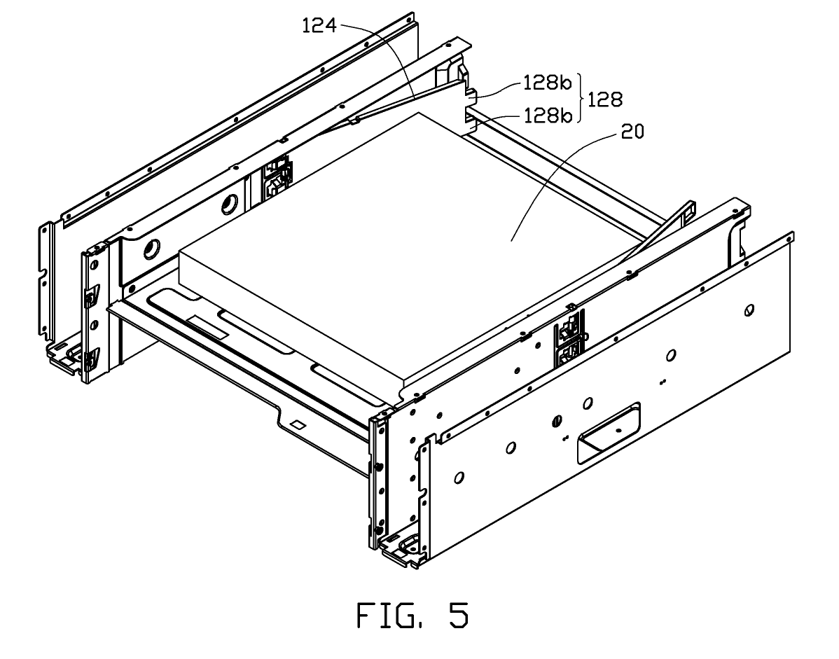

Referring to FIG. 5, when the module 20 is inserted into the receiving space 116 via the module entry 116a, the module 20 drives the two baffles 122a to overcome the torque force generated by the resisting portion 122f. The two baffles 122a rotate around the shafts 122b and the two baffles 122a are unlatched from each other. The module 20 is finally fixed between the two baffles 122a in the receiving space 116. When the module 20 is removed from the receiving space 116 via the module entry 116a, the two baffles 122a rotate back under the restoring force generated by the torsion spring 122c, until the two baffles 122a are latched together again.

To make the baffles 122a firmly latch to each other after the module 20 is removed, each resisting assembly 122 may further includes a restricting member 129. The restricting member 129 is formed on the corresponding sidewall 116c and positioned beside the corresponding shaft 122b. The restricting member 129 resists the securing block 126a of the corresponding baffle 122a to limit a rotation range of the baffle 122a toward the module entry 116a, so as to prevent the two baffles 122a from being detached by air introduced from the air inlet 116b.

It is to be understood, however, that even though numerous characteristics and advantages of the embodiments have been set forth in the foregoing description, together with details of the structures and functions of the embodiments, the disclosure is illustrative only, and changes may be made in detail, especially in matters of arrangement of parts within the principles of the invention to the full extent indicated by the broad general meaning of the terms in which the appended claims are expressed.

What is claimed is:

1. A server rack for receiving a plurality of modules, the server rack comprising:
two parallel side plates;
a clapboard disposed between the two side plates and being substantially perpendicular to the two side plates to form a receiving space, the receiving space defining an air inlet and a module entry opposite to the air inlet; and
a baffle device received in the receiving space, the baffle device comprising:
two resisting assemblies installed on the two side plates oppositely, each resisting assembly comprising:
a baffle, the baffle comprising:
a securing portion rotatablely secured on the corresponding side plate; and
a latching portion opposite to the securing portion;
wherein a total length of the two baffles is larger than the width of the receiving space, the two baffles are inclined toward the air inlet, and the two latching portions of the two baffles are latched facing the air inlet, to cover the module entry when no module is received in the receiving space.

2. The server rack of claim 1, wherein each resisting assembly comprises a shaft and a torsion spring, the receiving space defines two sidewalls formed on the inner sidewalls of the two side plates oppositely, the securing portion of the baffle is secured rotatably on a corresponding sidewall by the shaft, the torsion spring is sleeved around the shaft, one end of the torsion spring is mounted on the corresponding sidewall, the other end of the torsion spring abuts the corresponding baffle.

3. The server rack of claim 2, wherein each sidewall of the receiving space comprises a curtain board extending from the top of each sidewall toward the receiving space, the clapboard defines two first through holes corresponding to each resisting assembly, the curtain board defines two second through holes opposite to the first through holes correspondingly, the torsion spring comprises two coil portions, the securing portion of each baffle defines a third through hole, the shaft is inserted into a corresponding one of the second through holes, the third through hole, the coil portion, and the corresponding one of the first through holes in turn to allow each baffle to be secured rotatably on the corresponding sidewall.

4. The server rack of claim 3, wherein the securing portion of each baffle comprises two securing blocks spaced from each other and rotatably secured to each corresponding sidewall, the third through hole is defined in the securing blocks.

5. The server rack of claim 2, wherein each baffle further comprises a main body, the securing portion and the latching portion are disposed on the opposite ends of the main body, and the torsion spring comprises a resisting portion connected to the two coil portions and abuts the main body of the corresponding baffle.

6. The server rack of claim 5, wherein the main body of each baffle is substantially rectangular.

7. The server rack of claim 4, wherein the latching portion of each baffle comprises two latching blocks spaced from each other and a latching groove is formed between the two latching blocks.

8. The server rack of claim 4, wherein each resisting assembly further comprises a restricting member formed on the sidewall and positioned beside the shaft to resist the securing block to limit a rotation range of the baffle towards the module entry.
